(19) United States
(12) Patent Application Publication
(10) Pub. No.: US 2026/0344038 A1
(43) Pub. Date: Oct. 29, 2026

(54) SEMICONDUCTOR DEVICE

(71) Applicant: Vanguard International Semiconductor Corporation, Hsinchu (TW)

(72) Inventors: Cheng-Tsung Wu, Taipei City (TW); Fu-Chun Tseng, Taipei City (TW)

(73) Assignee: Vanguard International Semiconductor Corporation, Hsinchu (TW)

(21) Appl. No.: 19/193,904

(22) Filed: Apr. 29, 2025

(51) Int. Cl. H10D 84/85; H10D 84/83

(52) U.S. Cl. CPC H10D 84/856; H10D 84/835; H10D 84/854

(57) ABSTRACT

A semiconductor device includes a first well region having a first conductivity type and disposed in a substrate. A second well region has the first conductivity type, is disposed in the substrate, and surrounds the first well region. A third well region has a second conductivity type, is disposed in the substrate and between the first well region and the second well region, and surrounds the first well region. A source contact region is disposed in the second well region. A drain contact region is disposed in the first well region. A gate is disposed directly above the third well region. A buried layer has the second conductivity type, is disposed in the substrate, and extends laterally from directly below the third well region to directly below the second well region.

### BACKGROUND OF THE INVENTION

### 1. Field of the Invention

The present disclosure relates generally to semiconductor devices for switching circuits, and more particularly to semiconductor devices including a double-diffused metal-oxide-semiconductor (DMOS) transistor merged with the periphery of a level shifter region.

### 2. Description of the Prior Art

A switching circuit (or bridge circuit) usually includes a high-side (or upper bridge) element, a low-side (or lower bridge) element, a boost device, a level shift circuit, a high-side drive circuit, a low-side drive circuit, and control logic. In the switching circuit, the high-side element is electrically connected in series to the low-side element, and the high-side element and the low-side element are alternately turned on and off. In the boost device of the switching circuit, a bootstrap diode is disposed between a high-side voltage terminal and a low-side voltage terminal. When the high-side circuit is turned on, the bootstrap diode operates in reverse bias to prevent the high-voltage signal from damaging the low-side circuit. When the high-side circuit is turned off, the bootstrap diode operates in forward bias to use the low-side voltage to charge the capacitor in the boost device, thereby maintaining the high-side voltage at a certain level. However, in switching circuits, the current bootstrap diode architecture cannot meet the various requirements of integrated circuits.

### SUMMARY OF THE INVENTION

In view of this, the present disclosure provides semiconductor devices suitable for switching circuits. The semiconductor devices include a double-diffused metal-oxide-semiconductor (DMOS) transistor merged with the periphery of a level shifter region to replace the bootstrap diode architecture in a boost device. Moreover, a buried layer is disposed under both the channel region and the well region at the source of the DMOS transistor to reduce the parasitic NPN bipolar transistor effect, thereby avoiding or reducing substrate leakage current while not affecting the various electrical performances of the semiconductor devices.

According to an embodiment of the present disclosure, a semiconductor device is provided and includes a substrate, a first well region, a second well region, a third well region, a source contact region, a drain contact region, a gate, and a buried layer. The first well region has a first conductivity type and is disposed in the substrate. The second well region has the first conductivity type, is disposed in the substrate, and surrounds the first well region. The third well region has a second conductivity type, is disposed in the substrate and located between the first well region and the second well region, and surrounds the first well region. The source contact region is disposed in the second well region. The drain contact region is disposed in the first well region. The gate is disposed directly above the third well region. The buried layer has the second conductivity type, is disposed in the substrate, and extends laterally from directly below the third well region to directly below the second well region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic top view of a semiconductor device according to an embodiment of the present disclosure, showing the layout of a buried layer and some features.

FIG. 2 is a schematic cross-sectional view of a semiconductor device according to an embodiment of the present disclosure, taken along line A-A in FIG. 1.

FIG. 3 is a schematic cross-sectional view of a semiconductor device according to an embodiment of the present disclosure, taken along line B-B′ in FIG. 1.

FIG. 4 is a schematic top view of a semiconductor device according to another embodiment of the present disclosure, showing the layout of a buried layer having a racetrack-shaped pattern and some features.

FIG. 5 is a schematic cross-sectional view of a semiconductor device according to another embodiment of the present disclosure, taken along line C-C in FIG. 4.

FIG. 6 is a schematic cross-sectional view of a semiconductor device according to yet another embodiment of the present disclosure.

FIG. 7 is a schematic top view of a semiconductor device according to yet another embodiment of the present disclosure, showing the layout of a buried layer having a finger-shaped pattern and some features.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure relates to semiconductor devices that include a double-diffused metal-oxide-semiconductor (DMOS) transistor merged with the periphery of a level shifter region. These semiconductor devices are suitable for switching circuits, and the DMOS transistor replaces the bootstrap diode architecture in a boost device. Moreover, a buried layer is disposed under both the channel region and the well region at the source of the DMOS transistor. This buried layer reduces the parasitic NPN bipolar transistor effect, thereby avoiding or reducing substrate leakage current while not affecting the various electrical performances of the semiconductor devices. Therefore, the utilization of these semiconductor devices in integrated circuits is improved. In addition, the manufacturing of the DMOS transistor that includes the buried layer is integrated with the fabrication processes of the level shifter region. Therefore, the fabrication of the semiconductor devices does not require additional photomasks and process steps, thereby saving the manufacturing cost of the semiconductor devices.

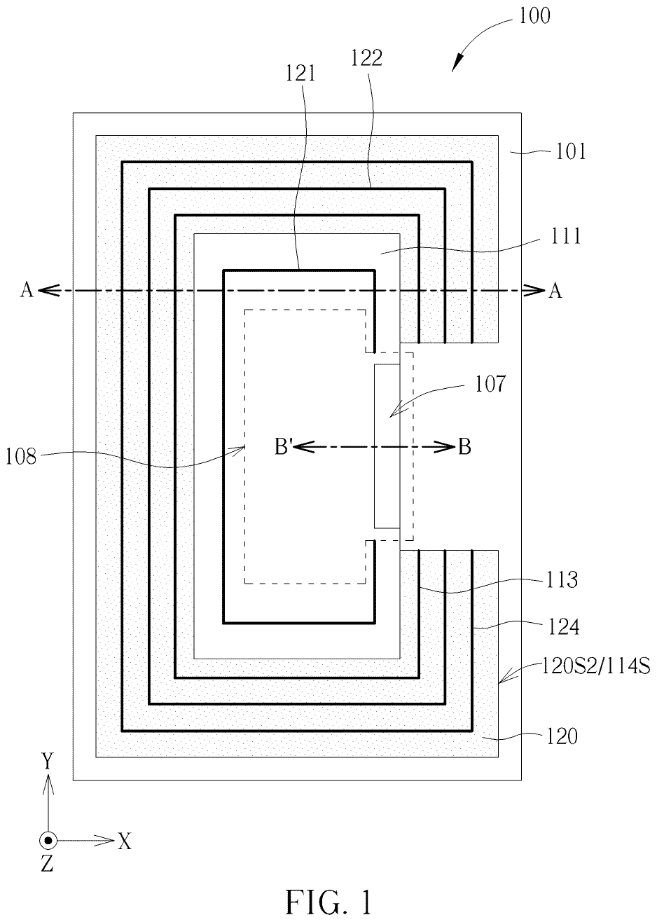

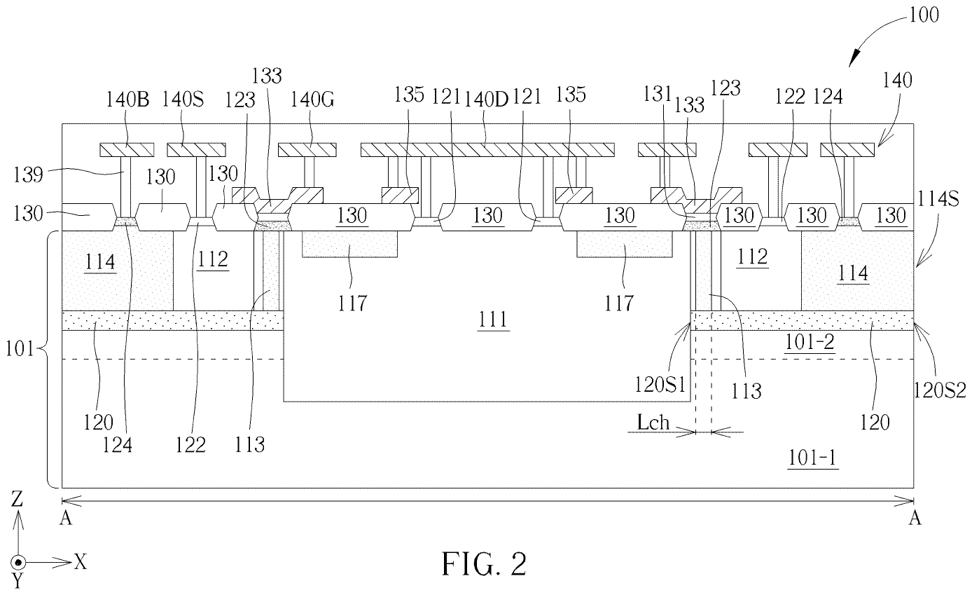

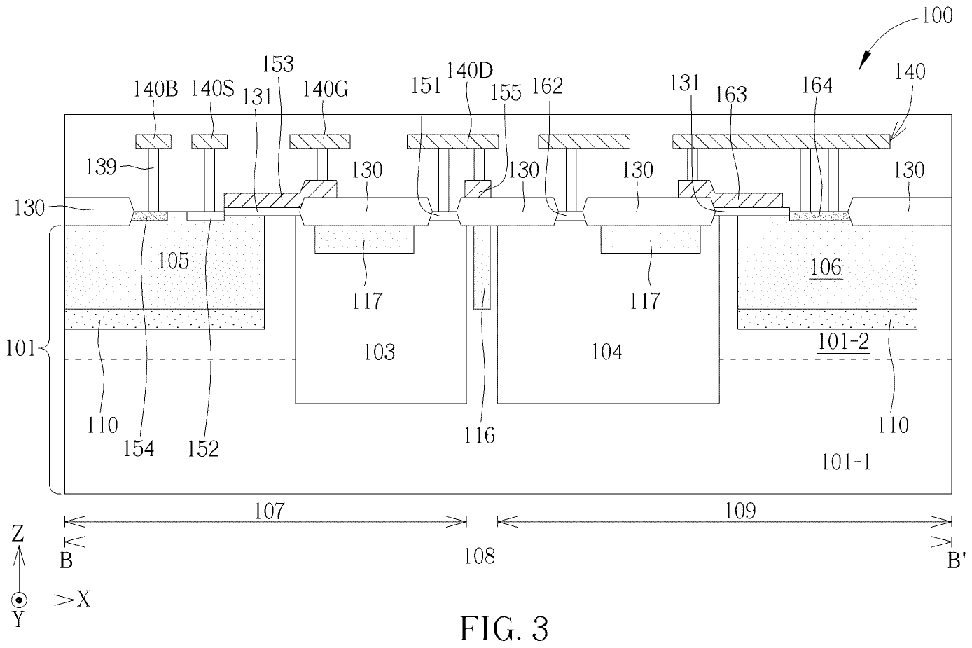

FIG. 1 is a schematic top view of a semiconductor device 100 according to an embodiment of the present disclosure, showing the layout of a buried layer 120 and some features, where the buried layer 120 has a rectangular pattern. To make the drawing concise and easy to understand, FIG. 1 shows a substrate 101, a level shifter region 108, and a DMOS transistor merged with the periphery of the level shifter region 108 in the semiconductor device 100. Moreover, a first well region 111, a third well region 113, the buried layer 120, a drain contact region 121, a source contact region 122, and a bulk contact region 124 of the DMOS transistor are also shown in FIG. 1. The other features of the semiconductor device 100 (not shown in FIG. 1) will be illustrated in subsequent FIG. 2 and FIG. 3.

Referring to FIG. 1, the first well region 111 is disposed in the substrate 101, and the drain contact region 121 is disposed on the first well region 111. The level shifter region 108 is also disposed in the substrate 101. When viewed from a top view, the buried layer 120 surrounds both the level shifter region 108 and the first well region 111. In addition, the third well region 113 is disposed on the buried layer 120. The source contact region 122 is disposed above the buried layer 120. The third well region 113 serves as a channel region of the DMOS transistor and is located between the drain contact region 121 and the source contact region 122. In this embodiment, the bulk contact region 124 is also disposed above the buried layer 120 and surrounds the source contact region 122. The vertical projection area of the buried layer 120 exceeds the bulk contact region 124. In one embodiment, an outer side surface 120S2 of the buried layer 120 may be vertically aligned with an outer side surface 114S of a fourth well region (not shown) where the bulk contact region 124 is disposed. Furthermore, the level shifter region 108 may include a transistor 107 located on one side, and the buried layer 120 may surround the level shifter region 108 continuously or discontinuously but does not surround the transistor 107. In one embodiment, as shown in FIG. 1, the buried layer 120 may be a C-shaped ring region continuously surrounding the level shifter region 108. In another embodiment, the buried layer 120 may be composed of multiple separated blocks, thereby discontinuously surrounding the level shifter region 108. To clearly show some features of the semiconductor device 100, the sizes of some features other than the level shifter region 108 are enlarged in FIG. 1. In practice, the sizes of these features may be adjusted according to layout requirements.

FIG. 2 is a schematic cross-sectional view of the semiconductor device 100 according to an embodiment of the present disclosure, taken along line A-A in FIG. 1 to illustrate the DMOS transistor merged with the periphery of the level shifter region 108. Referring to FIG. 2, the semiconductor device 100 includes the substrate 101. In one embodiment, the substrate 101 is constructed by, for example, stacking a p-type epitaxial layer 101-2 on a p-type substrate 101-1. Moreover, the semiconductor device 100 includes the first well region 111 disposed in the substrate 101. The first well region 111 has a first conductivity type and is constructed by, for example, stacking a high voltage n-type well region (HVNW) on a high voltage n-type deep well region (DHVNW). The drain contact region 121 is disposed in the first well region 111. The drain contact region 121 has the first conductivity type, such as an n-type heavily doped region (N⁺). The second well region 112 is disposed in the substrate 101 and surrounds the first well region 111. The second well region 112 has the first conductivity type, such as an n-type well region (NW). The bottom surface of the second well region 112 is higher than the bottom surface of the first well region 111. The source contact region 122 is disposed in the second well region 112. The source contact region 122 has the first conductivity type, such as an n-type heavily doped region (N⁺).

The third well region 113 is disposed in the substrate 101, located between the first well region 111 and the second well region 112, and surrounds the first well region 111. The third well region 113 is laterally separated from both the first well region 111 and the second well region 112. The third well region 113 has a second conductivity type and is, for example, a p-type well region (PW). A p-type heavily doped region (P⁺) 123 is disposed on the third well region 113. A fourth well region 114 is disposed in the substrate 101, surrounding and abutting the second well region 112. The bottom surfaces of the fourth well region 114 and the second well region 112 may be at the same level in height. The fourth well region 114 has the second conductivity type, such as a p-type well region (PW). The bulk contact region 124 is disposed in the fourth well region 114. The bulk contact region 124 has the second conductivity type, such as a p-type heavily doped region (P⁺).

Multiple isolation regions 130, such as field oxide (FOX) or shallow trench isolation (STI) structures, are disposed on the substrate 101 and located between the bulk contact region 124, the source contact region 122, the p-type heavily doped region 123, and the drain contact region 121. A gate 133 is disposed directly above the third well region 113 and may be composed of polysilicon. The third well region 113 serves as the channel region of the DMOS transistor, and a channel length Lch is the length of the third well region 113 in the direction (X-axis direction) from the first well region 111 to the second well region 122. A gate dielectric layer 131 is disposed below the gate 133 and between the gate 133 and the p-type heavily doped region (P⁺) 123. In addition, a p-type top layer (PTOP) 117 may be disposed in the first well region 111 and located directly below the isolation region 130 between the gate 133 and the drain contact region 121, thereby reducing the surface electric field. A field plate 135 is disposed on the isolation region 130 directly above the p-type top layer 117 and adjacent to the drain contact region 121, thereby dispersing the electric field. The field plate 135 may be composed of polysilicon and formed simultaneously with the gate 133 through deposition and patterning processes. Moreover, a portion of the gate 133 may extend laterally onto the isolation region 130 to serve as another field plate. A metal layer 140 is disposed above the substrate 101. The metal layer 140 may include a bulk electrode 140B, a source electrode 140S, a gate electrode 140G, and a drain electrode 140D. These electrodes are electrically connected to the bulk contact region 124, the source contact region 122, the gate 133, the field plate 135, and the drain contact region 121, respectively, through multiple conductive vias 139. These conductive via 139, the gate 133, and the field plate 135 may be disposed in an interlayer dielectric (ILD) layer (not shown), and the metal layer 140 may be formed on the ILD layer.

According to some embodiments of the present disclosure, the semiconductor device 100 further includes the buried layer 120 disposed in the substrate 101, extending laterally along the XY plane direction at least from directly below the third well region 113 to directly below the second well region 112. An inner side surface 120S1 of the buried layer 120 is in direct contact with a side surface of the first well region 111. The buried layer 120 has the second conductivity type, such as a p-type buried layer (PBL). The doping concentration of the buried layer 120 is higher than that of the substrate 101 and lower than that of the third well region 113. In some embodiments, the doping concentration of the buried layer 120 is, for example, about 1E17 cm⁻³ to about 1E18 cm⁻³. In this embodiment, the buried layer 120 further extends laterally from directly below the second well region 112 to directly below the fourth well region 114. From a top view, an outer side surface 120S2 of the buried layer 120 may be vertically aligned with an outer side surface 114S of the fourth well region 114. The vertical projection area of the buried layer 120 may be larger than the sum of the vertical projection areas of the second well region 112, the third well region 113, and the fourth well region 114. In one embodiment, the top surface of the buried layer 120 may be in direct contact with the bottom surfaces of the second well region 112, the third well region 113, and the fourth well region 114. In another embodiment, the top surface of the buried layer 120 may be in direct contact with the bottom surface of the third well region 113 and is slightly lower than the bottom surfaces of the second well region 112 and the fourth well region 114. In addition, the bottom surface of the buried layer 120 is higher than the bottom surface of the first well region 111.

In the semiconductor device 100, the first well region 111 (NW), the third well region 113 (PW), and the second well region 112 (NW) generate a parasitic NPN bipolar transistor. When the p-type dopant concentration at the bottom of the parasitic NPN bipolar transistor is higher, and/or the width of the p-type doped region at the bottom of the parasitic NPN bipolar transistor on the XY plane is larger, the β current gain value (beta gain) of the parasitic NPN bipolar transistor is reduced. The lower the β current gain value, the smaller the current amplification factor passing through the substrate 101, thereby avoiding or reducing substrate leakage current. According to some embodiments of the present disclosure, the doping concentration of the buried layer 120 is higher than that of the substrate 101. The doping concentration of the buried layer 120 is higher than that of the p-type epitaxial layer 101-2 and also higher than that of the p-type substrate 101-1. Furthermore, the buried layer 120 extends laterally at least from directly below the third well region 113 to directly below the second well region 112. In a comparative example, there is no buried layer 120 directly below the third well region 113, the second well region 112, and the fourth well region 114, so that the bottom of the parasitic NPN bipolar transistor in the comparative example is the p-type epitaxial layer 101-2 with a lower doping concentration. Compared to the comparative example, the embodiments of the present disclosure effectively reduce the parasitic NPN bipolar transistor effect generated by the first well region 111 (NW), the third well region 113 (PW), and the second well region 112 (NW), thereby reducing the β current gain value. Therefore, even under the operating condition of increased current, the semiconductor devices of the present disclosure still effectively avoid or reduce the substrate leakage current. In addition, the buried layer 120 does not affect various electrical performances of the semiconductor device 100, such as the threshold voltage (Vt), drive current (Ion), saturation current (Isat), off-state breakdown voltage (BVoff), and n-type well junction breakdown voltage (NW junction BV). These electrical performances are not affected by the buried layer 120.

FIG. 3 is a schematic cross-sectional view of a semiconductor device 100 according to an embodiment of the present disclosure, taken along line B-B′ in FIG. 1 to illustrate the level shifter region 108, and includes the transistor 107 and a high-side element 109. In one embodiment, the transistor 107 includes a first high-voltage well region 103, a fifth well region 105, and a p-type buried layer (PBL) 110, all disposed in the substrate 101. The first high-voltage well region 103 may be constructed by stacking a high-voltage n-type well region (HVNW) on a high-voltage n-type deep well region (DHVNW). The fifth well region 105 is, for example, a p-type well region (PW). The p-type buried layer 110 is located directly below the fifth well region 105. The fifth well region 105 and the p-type buried layer 110 are both laterally separated from the first high-voltage well region 103. A drain contact region 151 is disposed in the first high-voltage well region 103. A source contact region 152 and a bulk contact region 154 are both disposed in the fifth well region 105. The drain contact region 151 and the source contact region 152 are, for example, both n-type heavily doped regions (N⁺). The bulk contact region 154 is, for example, a p-type heavily doped region (P⁺). A gate 153 is disposed on the substrate 101, and a gate dielectric layer 131 is disposed between the gate 153 and the substrate 101. An isolation region 130 is disposed between the gate 153 and the drain contact region 151. A p-type top layer 117 is disposed directly below the isolation region 130 to reduce the surface electric field.

Still referring to FIG. 3, the high-side element 109 includes a second high-voltage well region 104, a sixth well region 106, and a p-type buried layer 110, all disposed in the substrate 101. The second high-voltage well region 104 may be constructed by stacking a high-voltage n-type well region (HVNW) on a high-voltage n-type deep well region (DHVNW). The sixth well region 106 is, for example, a p-type well region (PW). The p-type buried layer 110 is located directly below the sixth well region 106. The sixth well region 106 and the p-type buried layer 110 are both laterally separated from the second high-voltage well region 104. In addition, a p-type well region 116 is disposed between the first high-voltage well region 103 of the transistor 107 and the second high-voltage well region 104 of the high-side element 109. The p-type well region 116 serves as an isolation ring to isolate the transistor 107 from the high-side element 109. A field plate 155 is disposed on an isolation region 130 above the p-type well region 116. An n-type heavily doped region (N⁺) 162 is disposed in the second high-voltage well region 104. A p-type heavily doped region (P⁺) 164 is disposed in the sixth well region 106. A gate 163 is disposed on the substrate 101, and a gate dielectric layer 131 is disposed between the gate 163 and the substrate 101. An isolation region 130 is disposed between the n-type heavily doped region (N⁺) 162 and the gate 163. Another p-type top layer 117 is disposed directly below the isolation region 130 to reduce the surface electric field. A metal layer 140 is disposed above the substrate 101. The metal layer 140 includes multiple electrodes that are laterally separated from each other. Some of these electrodes are electrically connected to the bulk contact region 154, the source contact region 152, the gate 153, the drain contact region 151, and the field plate 155 of the transistor 107 through multiple conductive vias 139, respectively. Other electrodes are electrically connected to the n-type heavily doped region 162, the gate 163, and the p-type heavily doped region 164 of the high-side element 109 through multiple conductive vias 139, respectively.

The manufacturing of the DMOS transistor, merged with the periphery of the level shifter region 108, is integrated with the manufacturing processes of the level shifter region 108. The first well region 111 of the DMOS transistor, and both the first high-voltage well region 103 and the second high-voltage well region 104 of the level shifter region 108, are simultaneously formed through the same ion implantation process. The fourth well region 114 of the DMOS transistor, and both the fifth well region 105 and the sixth well region 106 of the level shifter region 108, are simultaneously formed through the same ion implantation process. The buried layer 120 of the DMOS transistor and the p-type buried layer 110 of the level shifter region 108 are simultaneously formed through the same ion implantation process. The buried layer 120 and the p-type buried layer 110 have the same conductivity type and the same doping concentration. The bottom surfaces of the buried layer 120 and the p-type buried layer 110 are substantially at the same level in height. In addition, the ion implantation process for forming the buried layer 120 and the p-type buried layer 110 is performed after the second well region 112, the third well region 113, and the fourth well region 114 are formed, thereby preventing various electrical performances of the semiconductor device 100 from being affected. Other features of the DMOS transistor and other similar features in the level shifter region 108 with the same conductivity type, for example, heavily doped regions, may be formed simultaneously through the same process steps. Moreover, p-type top layers, isolation regions, gates, and field plates of both the DMOS transistor and the level shifter region 108 may also be formed simultaneously through the same process steps. Therefore, according to the embodiments of the present disclosure, the manufacturing of the DMOS transistor that includes the buried layer 120 and is merged with the periphery of the level shift region 108 does not require additional photomasks and process steps, thereby saving the manufacturing cost of the semiconductor devices.

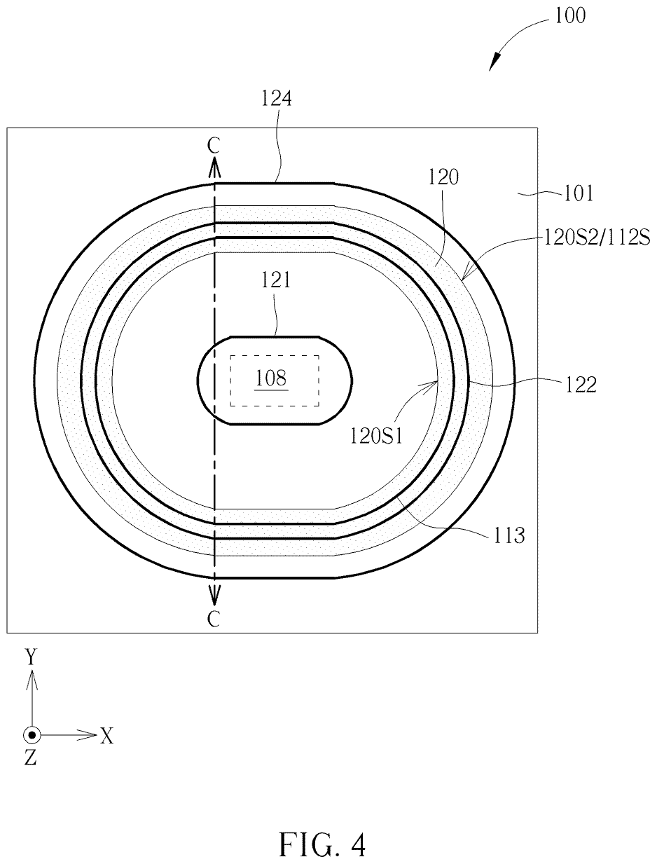

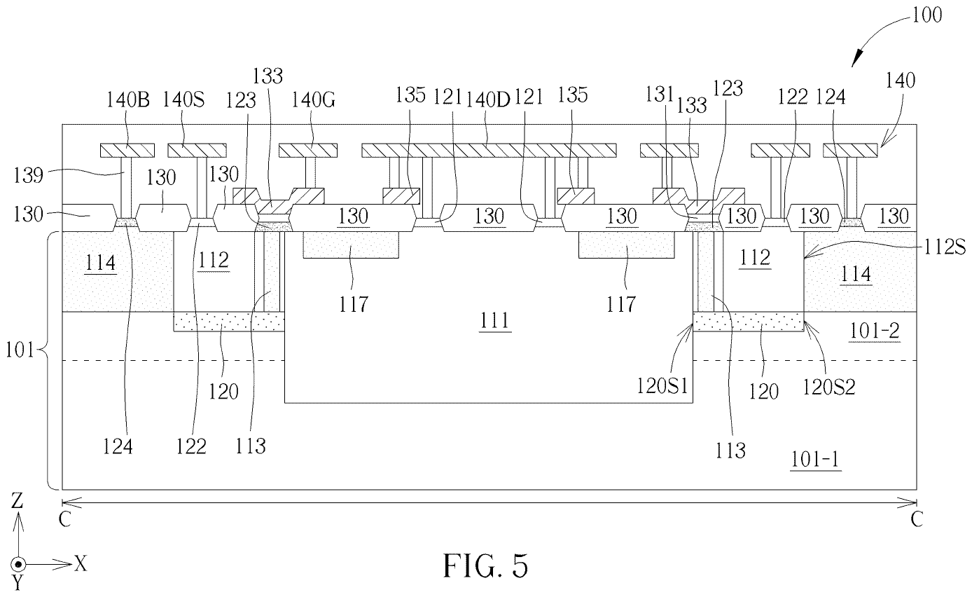

FIG. 4 is a schematic top view of a semiconductor device 100 according to another embodiment of the present disclosure, where a DMOS transistor is merged with the periphery of the level shifter region 108, and the buried layer 120 of the DMOS transistor has a racetrack-shaped pattern. To make the drawing concise and easy to understand, FIG. 4 shows the substrate 101 and the level shifter region 108 of the semiconductor device 100, together with the third well region 113, the buried layer 120, the drain contact region 121, the source contact region 122, and the bulk contact region 124 of the DMOS transistor. Other features of the semiconductor device 100 are illustrated in subsequent FIG. 5. As shown in FIG. 4, in one embodiment, the DMOS transistor is merged with the periphery of the level shifter region 108 and has a racetrack-shaped pattern. The drain contact region 121, the source contact region 122, the bulk contact region 124, the third well region 113, and the buried layer 120 all surround the level shifter region 108 and have a racetrack-shaped layout. To clearly show some features of the semiconductor device 100, the sizes of some features other than the level shifter region 108 are enlarged in FIG. 4. In practice, the size ratio of the level shifter region 108 may be larger. In this embodiment, from a top view, an outer side surface 120S2 of the buried layer 120 is within the bulk contact region 124. The third well region 113 corresponds to the racetrack-shaped pattern of the buried layer 120 and is disposed directly above the buried layer 120.

FIG. 5 is a schematic cross-sectional view of a semiconductor device 100 according to another embodiment of the present disclosure, taken along line C-C in FIG. 4 to show the DMOS transistor merged with the periphery of the level shifter region 108. In this embodiment, the buried layer 120 extends laterally from directly below the third well region 113 to directly below the second well region 112. The outer side surface 120S2 of the buried layer 120 is vertically aligned with the outer side surface 112S of the second well region 112, and the buried layer 120 does not extend directly below the fourth well region 114. The vertical projection area of the buried layer 120 is greater than the sum of the vertical projection areas of the second well region 112 and the third well region 113. The details of other features of the semiconductor device 100 in FIG. 5 may refer to the aforementioned description of the semiconductor device 100 in FIG. 2, and will not be repeated here.

In addition, when the element adjacent to the semiconductor device 100 does not use an n-type well region as a major portion, for example, when the adjacent element is not a PMOS transistor, referring to FIG. 5, the p-type buried layer 120 does not extend directly below the fourth well region 114. When the element adjacent to the semiconductor device 100 uses an n-type well region as a major portion, for example, when the adjacent element is a PMOS transistor, referring to FIG. 2, the p-type buried layer 120 further extends directly below the fourth well region 114, thereby reducing the parasitic NPN bipolar transistor effect between the n-type well region of the adjacent element and both the second well region 112 (NW) and the fourth well region 114 (PW) of the semiconductor device 100.

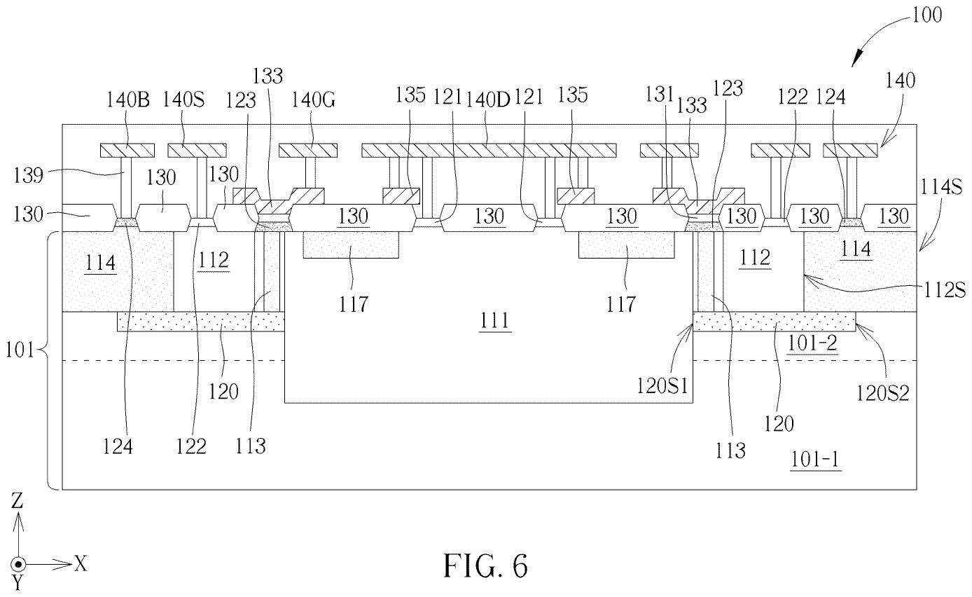

FIG. 6 is a schematic cross-sectional view of a semiconductor device 100 according to yet another embodiment of the present disclosure, showing a DMOS transistor merged with the periphery of a level shifter region. In this embodiment, the buried layer 120 extends laterally from directly below the third well region 113 to directly below the second well region 112, and further extends laterally to directly below a portion of the fourth well region 114. For example, the buried layer 120 may extend directly below the bulk contact region 124. From a top view, the outer side surface 120S2 of the buried layer 120 is located between the outer side surface 112S of the second well region 112 and the outer side surface 114S of the fourth well region 114. The buried layer 120 in the embodiment of FIG. 6 also reduces the parasitic NPN bipolar transistor effect generated by the first well region 111 (NW), the third well region 113 (PW), and the second well region 112 (NW), thereby reducing the β current gain value to avoid or reduce substrate leakage current. The details of other features of the semiconductor device 100 in FIG. 6 may refer to the aforementioned description of the semiconductor device 100 in FIG. 2, and will not be repeated here.

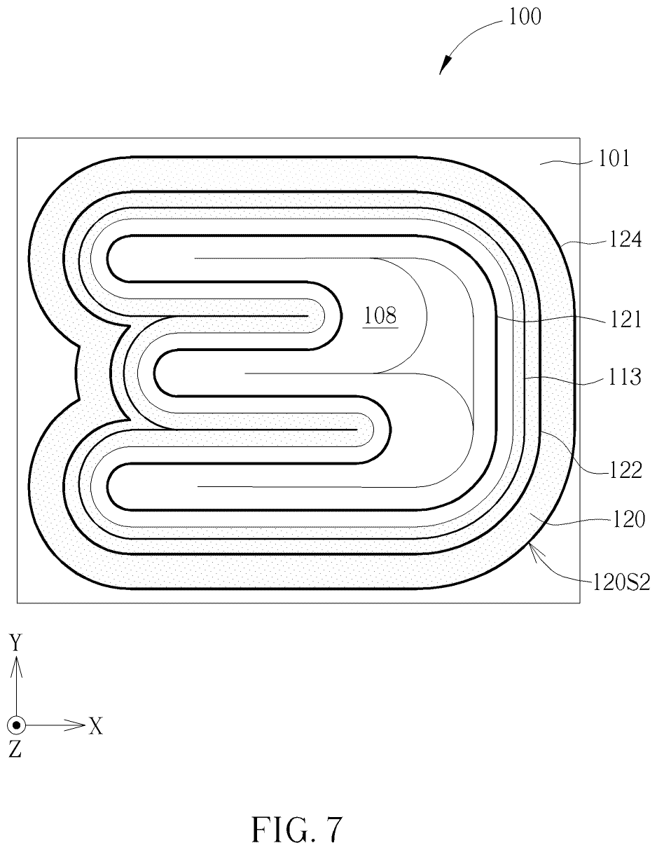

FIG. 7 is a schematic top view of a semiconductor device 100 according to another embodiment of the present disclosure, where a DMOS transistor is merged with the periphery of the level shifter region 108, and the buried layer 120 of the DMOS transistor has a finger-shaped pattern. To make the drawing concise and easy to understand, FIG. 7 shows the substrate 101 and the level shifter region 108 of the semiconductor device 100, together with the third well region 113, the buried layer 120, the drain contact region 121, the source contact region 122, and the bulk contact region 124 of the DMOS transistor. The other features of the semiconductor device 100 (not shown in FIG. 7) may refer to the aforementioned description of FIG. 2. Referring to FIG. 7, in one embodiment, the DMOS transistor merged with the periphery of the level shifter region 108 has a finger-shaped pattern. The drain contact region 121, the source contact region 122, the bulk contact region 124, the third well region 113, and the buried layer 120 all surround the level shifter region 108 and all have a finger-shaped layout. From a top view, the third well region 113 corresponds to the finger-shaped pattern of the buried layer 120 and is disposed directly above the buried layer 120. To clearly show some features of the semiconductor device 100, the sizes of some features other than the level shifter region 108 are enlarged in FIG. 7. The size ratio of the level shifter region 108 and the DMOS transistor may be adjusted according to actual requirements. In the embodiment of FIG. 7, referring to FIG. 6 together, the outer side surface 120S2 of the buried layer 120 may be substantially vertically aligned with the bulk contact region 124.

According to some embodiments of the present disclosure, the semiconductor devices include a DMOS transistor merged with the periphery of the level shifter region, and the DMOS transistor includes a buried layer. The buried layer has the second conductivity type and is, for example, a p-type buried layer (PBL). The buried layer extends laterally at least from directly below the third well region in the channel region to directly below the second well region in the source region. The third well region has the second conductivity type and is, for example, a p-type well region (PW). The second well region has the first conductivity type, and is, for example, an n-type well region (NW). The first well region has the first conductivity type and is, for example, an n-type well region (NW). This buried layer (PBL) reduces the parasitic NPN bipolar transistor effect generated by the first well region (NW), the third well region (PW), and the second well region (NW), thereby reducing the β current gain value. Therefore, the substrate leakage current of the semiconductor devices is avoided or reduced. Meanwhile, the various electrical performances of the semiconductor devices are not affected, thereby improving the utilization of the semiconductor devices in integrated circuits.

Furthermore, according to some embodiments of the present disclosure, the manufacturing of the DMOS transistor that includes the buried layer is integrated with the manufacturing processes of the level shifter region. The fabrication of the semiconductor devices does not require additional photomasks and process steps, thereby saving the manufacturing cost of the semiconductor devices.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a first well region, having a first conductivity type and disposed in the substrate;
a second well region, having the first conductivity type, disposed in the substrate, and surrounding the first well region;
a third well region, having a second conductivity type, disposed in the substrate, located between the first well region and the second well region, and surrounding the first well region;
a source contact region, disposed in the second well region;
a drain contact region, disposed in the first well region;
a gate, disposed directly above the third well region; and
a buried layer, having the second conductivity type, disposed in the substrate, and extending laterally from directly below the third well region to directly below the second well region.

2. The semiconductor device of claim 1, wherein a vertical projection area of the buried layer is larger than the sum of vertical projection areas of the second well region and the third well region.

3. The semiconductor device of claim 1, wherein a top surface of the buried layer is in direct contact with a bottom surface of the second well region and a bottom surface of the third well region.

4. The semiconductor device of claim 1, wherein an outer side surface of the buried layer is vertically aligned with an outer side surface of the second well region.

5. The semiconductor device of claim 1, further comprising:
a fourth well region, having the second conductivity type, disposed in the substrate, surrounding and abutting the second well region; and
a bulk contact region, disposed in the fourth well region, wherein the buried layer extends laterally from directly below the second well region to directly below the fourth well region.

6. The semiconductor device of claim 5, wherein an outer side surface of the buried layer is vertically aligned with an outer side surface of the fourth well region.

7. The semiconductor device of claim 5, wherein from a top view, an outer side surface of the buried layer is located between an outer side surface of the second well region and an outer side surface of the fourth well region.

8. The semiconductor device of claim 5, wherein a vertical projection area of the buried layer is larger than the sum of vertical projection areas of the second well region, the third well region, and the fourth well region.

9. The semiconductor device of claim 5, wherein a top surface of the buried layer is in direct contact with a bottom surface of the second well region, a bottom surface of the third well region, and a bottom surface of the fourth well region.

10. The semiconductor device of claim 1, wherein an inner side surface of the buried layer is in direct contact with a side surface of the first well region.

11. The semiconductor device of claim 1, wherein a bottom surface of the buried layer is higher than a bottom surface of the first well region.

12. The semiconductor device of claim 1, wherein the third well region is laterally separated from both the first well region and the second well region.

13. The semiconductor device of claim 1, wherein the substrate has the second conductivity type, and a doping concentration of the buried layer is higher than a doping concentration of the substrate.

14. The semiconductor device of claim 1, wherein a doping concentration of the buried layer is lower than a doping concentration of the third well region.

15. The semiconductor device of claim 1, further comprising a level shifter region disposed in the substrate, wherein from a top view, the buried layer surrounds the level shifter region.

16. The semiconductor device of claim 15, wherein from the top view, the buried layer comprises a racetrack-shaped pattern or a finger-shaped pattern.

17. The semiconductor device of claim 16, wherein from the top view, the third well region corresponds to the racetrack-shaped pattern or the finger-shaped pattern, and the third well region is disposed directly above the buried layer.

18. The semiconductor device of claim 15, wherein from the top view, the buried layer continuously surrounds the level shifter region.

19. The semiconductor device of claim 15, wherein from the top view, the buried layer discontinuously surrounds the level shifter region.

20. The semiconductor device of claim 15, wherein the level shifter region comprises another buried layer having the second conductivity type and disposed in the substrate, the buried layer and the another buried layer have the same doping concentration, and a bottom surface of the buried layer and a bottom surface of the another buried layer are at the same level in height.
